(19) United States
(12) Patent Application Publication
(10) Pub. No.: US 2008/0001297 A1
(43) Pub. Date: Jan. 3, 2008

(54) Laser patterning and conductive interconnect/materials forming techniques for fine line and space features

(76) Inventors: Stefanie Lotz, Phoenix, AZ (US); Islam Salama, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/479,690

(22) Filed: Jun. 30, 2006

(51) Int. Cl. H01L 23/48

(52) U.S. Cl. 257/774

(57) ABSTRACT

Package substrates and methods to fabricate therein are described. A package substrate may include conductive layers, vias, dielectric layers and traces fabricated therein, all patterned on one or two sides of a core embedded within a package substrate. For an embodiment, vias and traces may be formed by an ablation process and a subsequent ink printing process. For other embodiments, vias and traces may be formed by various combinations of other processes such as, but not limited to, ablation, ink printing, paste deposition, and laser assisted deposition. For various embodiments, the traces may have aspect ratios greater than 1.

### FIELD

Embodiments of the invention relate generally to the field of semiconductor manufacturing, and more specifically, to semiconductor packages and methods to fabricate thereof.

### BACKGROUND

Advanced packages, such as flip chip Ball Grid Array (BGA), continue to drive the need for the most aggressive line and space geometries for package substrate designs. Currently, there are challenges to deliver both technical and cost effective solution for fabricating high density substrate packages with line space geometries less than 10 μm by extending the current semi-additive process (SAP) technology.

Today, the most advanced flip chip substrates are manufactured using semi-additive processing (SAP) technology, which can achieve fine line and space dimensions on the order of sub 15 μm in width and an aspect ratio of approximately 1. The SAP process flow uses a photolithography process to create metal line interconnect patterns. In this case, a dry film photoresist is patterned and used to create selective deposition of electroplated copper. The photoresist is removed subsequent to the plating processes whereby only the patterned copper lines remain. The photo-exposure equipment can either include laser imaging, or step and repeat photolithography at either h-line (405 nm) or i-line (365 nm) wavelengths. To achieve finer line widths (≦10 μm) continual improvements are being made in the areas of dry film resist patterning, reduced plating thickness variation, improved adhesion between copper to dielectric, as well as feature profile resistance to chemical etching. However at the present, these collective improvements are not capable of providing a technical solution for the 10 μm regime, as well as complying with the reduction in dimensional tolerances with each generation of line space shrink.

### BRIEF DESCRIPTION OF DRAWINGS

The present invention is illustrated by way of example and not limitation in the figures of the accompanying drawings, in which like references indicate similar elements, and in which:

FIG. 1 shows a cross-section of a package substrate having a core, conductive layers, a dielectric layer, vias, and traces fixed in a dielectric layer, all disposed on one side of a core according to an embodiment.

FIG. 2 shows a cross-section of a package substrate having a core, conductive layers, a dielectric layer, vias, and traces fixed in a dielectric layer, all disposed on two sides of a core according to an embodiment.

FIG. 3 shows a flowchart of embodiments of three methods for fabricating a package substrate.

FIGS. 4-9 are cross-sections of a package substrate illustrating a method for fabricating a package substrate according to a first embodiment.

FIGS. 10-15 are cross-sections of a package substrate illustrating a method for fabricating a package substrate according to a second embodiment.

FIGS. 16-20 are cross-sections of a package substrate illustrating a method for fabricating a package substrate according to a third embodiment.

### DETAILED DESCRIPTION

Package substrates and methods to fabricate thereof are described. For an embodiment, a package substrate includes a core, conductive layers, a dielectric layer, vias, and traces fixed in a dielectric layer, all disposed on one side of a core. For other embodiments, a package substrate includes a core, conductive layers, a dielectric layer, vias, and traces fixed in a dielectric layer, all disposed on two sides of a core. A package substrate may be fabricated by various processes such as, but not limited to, a semi-additive process (SAP), a laser ablation or laser projection patterning process, a direct write process such as, an ink printing process, a paste deposition process, and/or a laser assisted deposition process. For an embodiment when a laser ablation or laser projection patterning process is used in conjunction with a direct write process to fabricate a package substrate, a set of traces that are formed during the patterning process are fixed in a dielectric layer. Additionally, there are metallurgical distinctions between package substrate features formed by a direct write process and a laser and direct write combination process as the metallization occurs by way of conductive metal ink deposition versus traditional electroplating for embodiments that use a laser ablation process, the need for dry film resist (DFR) and subsequent lithography patterning techniques may be eliminated. Additionally, use of a direct write process to define features within a package substrate may minimize the exposure of a substrate panel to wet processing, which may improve panel dimensional stability and hence enable tighter alignment tolerances for feature formation within the package substrate. For embodiments that use an ink printing, paste deposition, or laser assisted deposition process is used to deposit conductive material, conventional planarization methods may not be required due to the precision achieved by use of the aforementioned deposition processes.

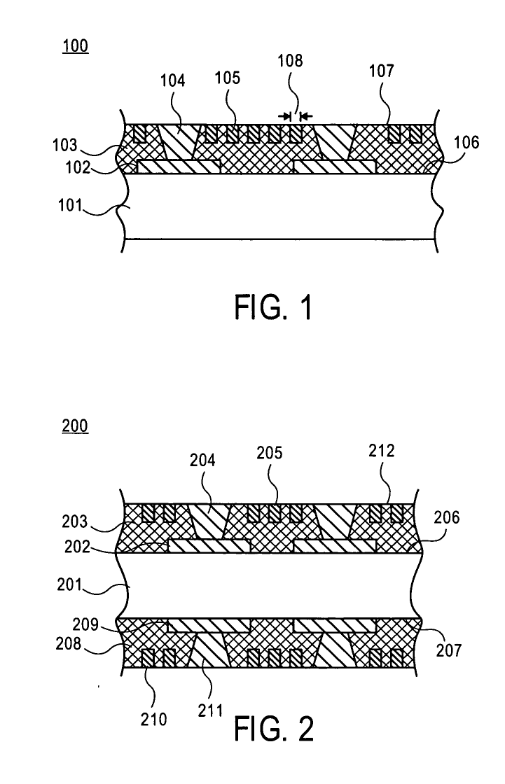

FIG. 1 shows a cross-section of a package substrate 100. As shown in FIG. 1, package substrate 100 features conductive layers 102, a first dielectric layer 103, vias 105, all disposed on a top side 106 of a core 101. As shown in FIG. 1, a core 101 may make up a significant portion of the area of package substrate 100. For various embodiments, the thickness of core 101 may range from 400 to 800 microns.

Package substrate 100 also features conductive layers 102 disposed flush to a top surface 106 of core 101. Conductive layers 102 may provide additional power for package substrate 100 and/or ground planes to improve electrical or thermal performance. Conductive layers 102 may include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. For one embodiment, conductive layers 102 includes a metal alloy or a compound that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. In other embodiments, conductive layers 102 may comprise another material or materials. Conductive layers 102 may have a thickness such that sufficient power, electrical, and thermal performance is provided. For one embodiment, the thickness of conductive layers 102 is approximately 20 microns. For various other embodiments, the thickness of conductive layers 102 may vary from 20 to 40 microns.

Package substrate 100 also features a first dielectric layer 103 disposed over top surface 106 of core 101. As shown in FIG. 1, first dielectric layer 103 is disposed over most areas of over top surface 106 not covered by conductive layers 102, vias 104, and traces 105. First dielectric layer 103 may include any suitable insulating material known in the art. For one embodiment, the thickness of first dielectric layer 103 is approximately 60 microns. For various other embodiments, the thickness of first dielectric layer 103 may vary from 20 to 60 microns.

Package substrate 100 also features via 104, as shown in FIG. 1, which extends through first dielectric layer 103 to conductive layers 102. For an embodiment, via 104 may electrically couple successive conductive layers 102 to a semiconductor die mounted on substrate 100. To facilitate coupling to a semiconductor die, via 104 may include a conductive material such as copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. For one embodiment, via 104 includes a metal alloy or a compound that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. For other embodiments, via 104 may comprise another material or materials.

As shown in FIG. 1, the distance that core 101 and conductive layer 102 are separated from the top surface 107 of package substrate 100 (or in the case of multiple conductive regions, each successive layer) is determined by the height of via 104. The height of via 104 may be defined as the distance between top surface 107 and the top surface of conductive layer 102. For one embodiment, the height of via 104 is approximately 60 microns. For other embodiments, the height of via 104 ranges from 20 to 60 microns.

Package substrate 100 also features traces 105 embedded in a portion of first dielectric layer 103. Conductive traces 105 may function within package substrate 100 to route signals between a semiconductor die and a motherboard through successive conductive layers 102 and vias 104. Traces 105 are disposed within first dielectric layer 103 such that a top surface of trace 105 is at the same height as top surface 107. A plurality of traces 105 may be disposed in first dielectric layer 103. For various embodiments, several hundred traces per mm density may be disposed within first dielectric layer 103.

The quantity of traces embedded within package substrate 101 may depend on the width 108 of each trace 105 disposed within the first dielectric layer 103. For an embodiment, the width 108 of trace 105 is less than 10 microns. For other embodiments the width 108 of trace 105 may range from 5 microns to 20 microns.

For the embodiment illustrated in FIG. 2, conductive layers, vias, traces, and dielectric layers are fabricated on two sides of a core. As shown, the features provided in package substrate 100 are disposed on a top surface 206 and a bottom surface 207 of core 201 within package substrate 200. Likewise, package substrate 200 features conductive layers 202, a first dielectric layer 203, vias 204, and traces 205 disposed on top surface 206 of core 201 and also features conductive layers 209, second dielectric layer 208, vias 211, and traces 210 disposed on a bottom surface 207 of core 201. For various embodiments, the dimensions, composition, and disposition of the layers and structures of package substrate 200 are characteristic of the aforementioned layers and structures featured in package substrate 100.

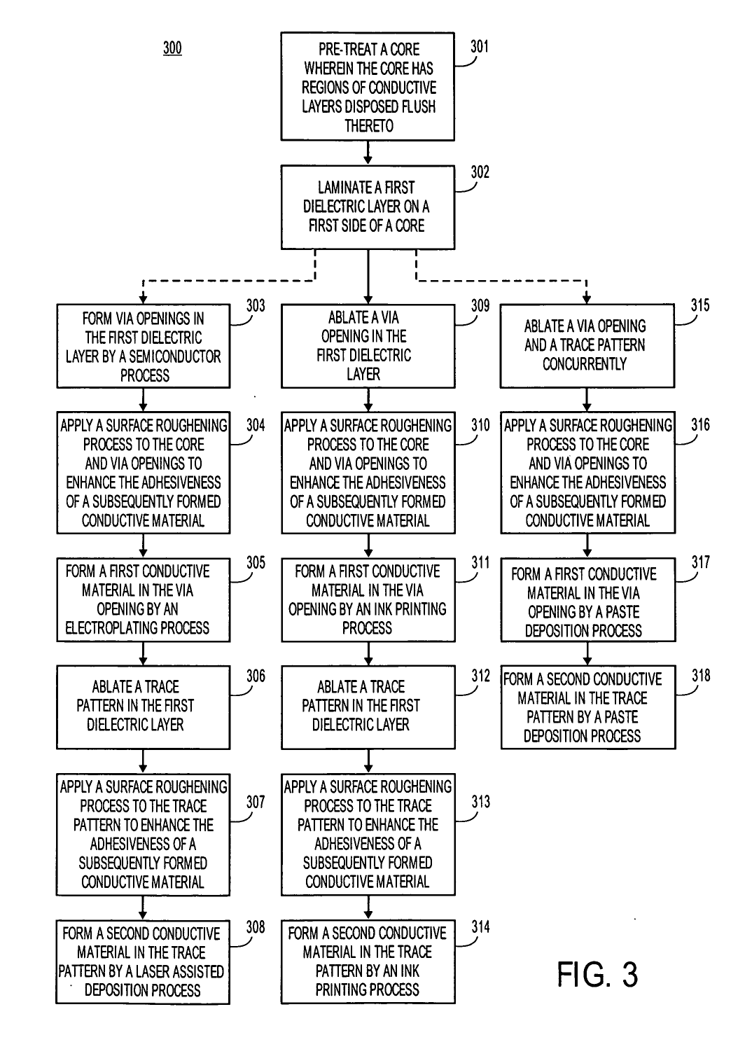

FIG. 3 shows flowchart 300 which illustrates three methods for forming a package substrate. The first method, defined as operations 301-302 and 315-318, features a method of forming a package substrate that includes a dual ablation process for forming both via openings and a trace pattern concurrently. The second process, defined by operations 301-308, utilizes lithography and etch processes to form via openings and a laser ablation or laser projection patterning to form a trace pattern. The third method, defined by operations 301-302 and 309-314, features an ablation process to form via openings and a trace pattern consecutively. The three aforementioned methods for forming a package substrate include forming various features on one side of a core within a package substrate. However, these methods may be used to form various features on both sides of a core within a package substrate.

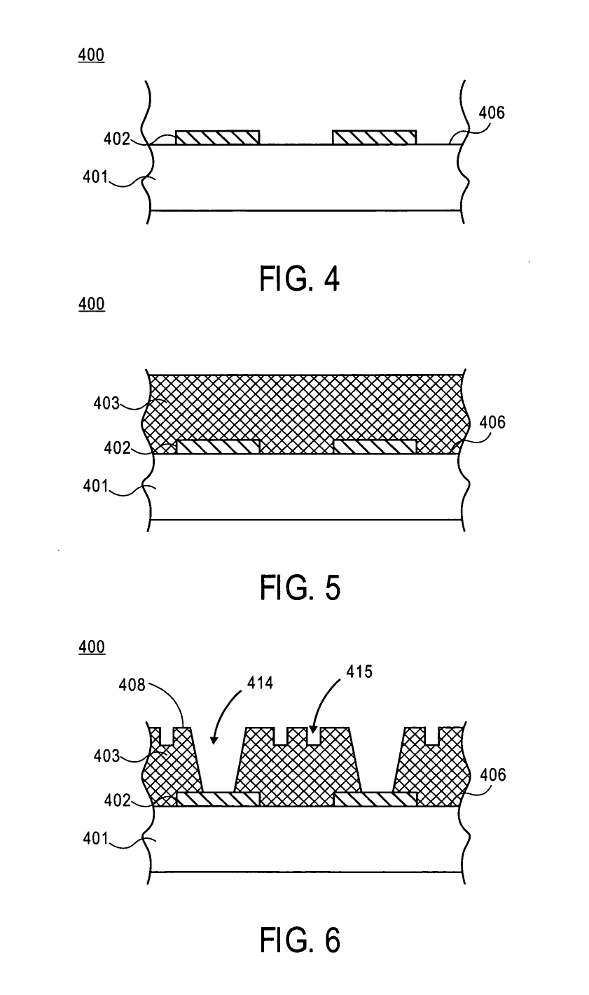

FIG. 4 is a cross-section of a substrate, illustrating the start of a method to fabricate a package substrate according to a process embodiment defined by operations 301-302 and 315-318. As shown, the process starts with a core 401 on which subsequent layers and structures may be fabricated upon. According to operation 301, core 401 is pre-treated which includes both a surface roughening process and formation of conductive layers 402. Surface roughening is known in the art and may include a process of abrading the top surface 406 of core 401 (mechanically, chemically, or both) to improve the adhesion of core 401 with subsequently formed layers and structures. Pre-treatment of core 401 may also include forming conductive layers 402. For an embodiment, conductive layers 402 may be formed by a conventional electroplating process. Conductive layers 402 may include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. For one embodiment, conductive layers 402 include a metal alloy or a compound that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. For other embodiments, conductive layers 402 may comprise another material or materials.

FIG. 5 shows the stage in the fabrication process of a package substrate after a first dielectric layer 403 is formed on the top surface 406 of core 401 (operation 302). For an embodiment, first dielectric layer 403 is formed by a lamination process such that a strip of dielectric material is laminated on the top surface 406 of core 401. First dielectric layer 403 may include any material such that conductive layers 402 are electrically isolated from successive conductive layers 402. First dielectric layer 403 may include any suitable insulating material known in the art. For one embodiment, the thickness of first dielectric layer 403 is approximately 60 microns. For other embodiments, the thickness of first dielectric layer 403 varies from 20 to 60 microns.

FIG. 6 shows the stage in the package substrate fabrication process after via openings 414 and trace pattern 415 are formed in first dielectric layer 403 (operation 315). For an embodiment, via openings 414 and trace pattern 415 may be fabricated simultaneously by an ablation process. Via openings 414 extend from the top surface of first dielectric layer 403 to an exposed conductive layers 402. Trace patterns 415 may extend through only a portion of first dielectric layer 403. For various embodiments, the depth of via openings 414 may range from 20-60 microns. For an embodiment, trace pattern 415 may have an aspect ratio greater than 1 and the height of trace pattern 415 is approximately 10 microns and the width of trace pattern 415 is approximately 5 microns. An aspect ratio is terminology common in the art and relates to the thickness of the metal lines to the width of the trace. A higher aspect ratio is desirable in that it enables higher speeds of data transfer, however higher aspect ratio signal lines have become increasing more challenging to fabricate with SAP processes as the line/space dimensions continue to shrink.

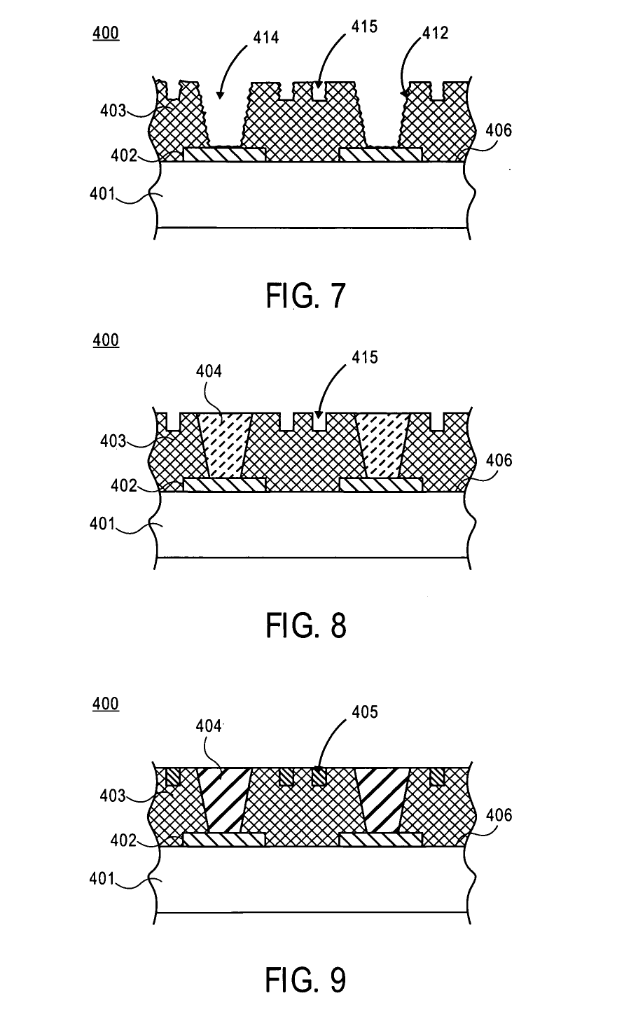

FIG. 7 shows the stage in the package substrate fabrication process after a surface roughening process is applied (operation 316). For an embodiment, a surface roughening process is applied to a substrate 400 to enhance the adhesion between conductive and non-conductive layers by abrading the exposed surface of conductive layers 402, via openings 414, trace pattern 415. As shown in FIG. 7, the aforementioned surfaces are slightly roughened 412, which illustrates an effect of the surface roughening process to the morphology of the exposed surfaces.

FIG. 8 shows the stage in the package substrate fabrication process after a conductive material is formed within via openings 414 (operation 317). For various embodiments, a conductive material may be formed in via openings 414 by various methods such as, but not limited to, electroplating, ink printing, laser assisted deposition, or paste deposition. For the embodiment shown in FIG. 8, a conductive material is formed by a paste deposition process. For an embodiment, the paste deposition process includes fabricating a stencil to match the pattern of via openings 414 and subsequently applying a stencil over via openings 414. Next, a squeegee tool is used to apply a paste material, conductive paste material 404, to the stencil. Then, a force is applied to the stencil thereby releasing the paste material from apertures in the squeegee into via openings 414. For an embodiment, the paste material applied to the stencil is a conductive material. Conductive paste material 404 may include copper (Cu), gold (Au), silver (Ag) lead (Pb), tin (Sn), or any combination thereof. For one embodiment, conductive paste material 404 includes a metal alloy or a compound that includes copper (Cu), gold (Au), silver (Ag), lead (Pb), tin (Sn) or any combination thereof. In other embodiments, conductive paste material 404 may comprise another material or materials. Conductive paste material 404 may have distinct metallurgical differences when compared to a conductive material formed by a electroplating, electro-less plating, or physical vapor deposition process. The metallurgical differences of conductive paste material 404 may be observed under a high power resolution electron microscope.

Conductive paste material 404 may have a considerable amount of porosity due to the paste deposition method of fabrication, which is illustrated in FIG. 8 by the dashed, diagonal lines. Likewise, according to an embodiment, the package substrate is subjected to a sintering process to densify conductive paste material 404 as a method to increase the conductivity. The sintering process may consist of thermal or laser processing to effectively eliminate solvents and enable particle coalescence to increase the conductivity by reducing the porosity of conductive paste material 404. As shown in FIG. 8, after the sintering process conductive paste material 404 has solid, diagonal lines to indicate sufficient densification.

FIG. 9 shows the stage of the fabrication process after a conductive material is formed in trace pattern 415 (operation 318). A conductive material may be formed in trace pattern 415 by any suitable process such as, but not limited to, ink printing deposition, laser assisted deposition, and paste deposition. For the embodiment shown in FIG. 9, a second paste conductive material 405 is formed by the aforementioned paste deposition process recited for the formation of first conductive paste material 404. Likewise, a sintering process may also be applied to the substrate 400 to reduce the porosity of second conductive paste material 405 and effectively increase its conductivity.

According to the first process taught above, a planarization process is not required due to the precision of the paste deposition process. Therefore, a chemical mechanical polish process (CMP) or any other planarization process is not required because the paste deposition process effectively deposits the conductive materials within the trenches and patterns without excess deposition that would otherwise result in electrical shorting.

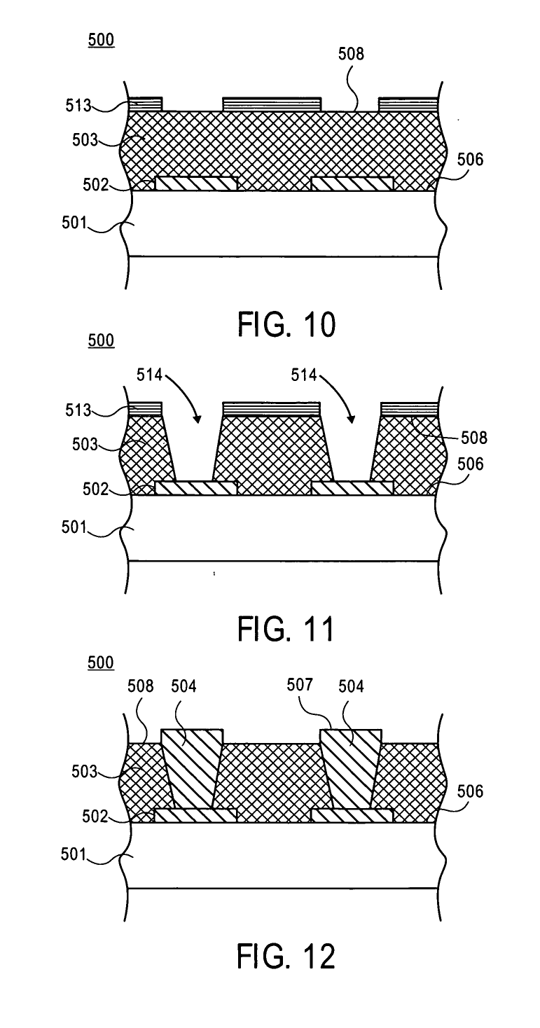

FIG. 10 is a cross-section of a substrate, illustrating the start of the second process, operations 301-308, to fabricate a package substrate after a core 501 is pre-treated and subsequently fabricated with conductive layers 502 and first dielectric layer 503 on a top surface 506 of core 501 (operations 301-302). As shown, a dry film resist pattern 513 is formed on first dielectric layer 503 which defines areas where vias will be subsequently formed (exposed surface 508). For various embodiments, dry film resist pattern 513 may comprise a positive or a negative resist.

FIG. 11 shows the process stage after via openings 514 are formed in first dielectric layer 503 (operation 303). Via openings 514 may be formed by a laser drilling, laser ablation patterning, photovia or any other chemical etching method process such that via openings 514 extend to and expose conductive layers 502. For an embodiment, a surface roughening process is applied to a substrate 500 to enhance the adhesion between a conductive and non-conductive by abrading the exposed surface of via openings 514 and the remainder of conductive layers 502 (operation 304).

FIG. 12 shows the process stage after a conductive material is formed in via openings 514 (operation 305). A conductive material may be formed by any suitable process such as, but not limited to, electroplating, ink printing, laser assisted deposition, and paste deposition. For the embodiment shown in FIG. 12, a first conductive material 504 may be formed in via openings 514 by an electroplating process. First conductive material 504 may include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. In one embodiment, first conductive material 504 include a metal alloy or a compound that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. In other embodiments, first conductive material 504 may comprise another material or materials.

As shown in FIG. 12, first conductive material 504 exceeds via openings 514 due to the precision limitations of an electroplating process. In response, a planarization technique is used to level a top surface 507 of first conductive material 504 with the top surface 508 of first dielectric layer 503.

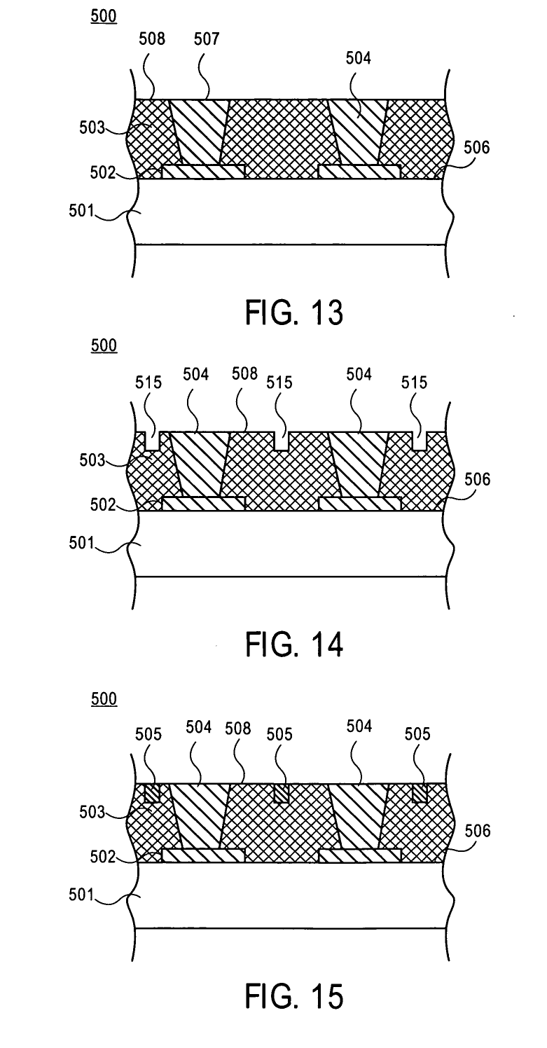

FIG. 13 shows the stage in the process after the package substrate is planarized such that the top surface 507 of first conductive material 504 is level with the top surface 508 of first dielectric layer 503. The substrate 500 may be planarized by various techniques such as, but not limited to, chemical mechanical polishing. Chemical mechanical polishing is a process known in the art and may include sanding the top surface 508 of first dielectric layer 503 in a circular motion with chemical slurries.

FIG. 14 shows the stage in the process after a trace pattern 515 is formed in a top portion of first dielectric layer 503 (operation 306). Trace pattern 515 may be formed by any suitable method in the art. For an embodiment, trace pattern 515 is formed such that an aspect ratio greater than 1 is achieved and the width of trace pattern 515 is less than ten microns. For the embodiment shown in FIG. 14, trace pattern 515 is formed by an ablation process. Trace pattern 515 may extend through only a portion of first dielectric layer 503. For an embodiment, trace pattern 515 may have a depth approximately 10 microns and a width less than or equal to 10 microns. For other embodiments, the height and width of trace pattern 515 may range from 10 to 20 microns such that the aspect ratio of the subsequently formed metal lines is greater than 1.

For an embodiment, a surface roughening process is applied to a substrate 500 to enhance the adhesion of a conductive material subsequently formed thereon by abrading the exposed surface of trace pattern 515 (operation 307). Although a surface roughening process is applied to a substrate 500, FIG. 14 may not show a roughened surface as previously illustrated in FIG. 7.

FIG. 15 shows the stage of the process after a conductive material is formed in trace pattern 515 (operation 308). A conductive material may be formed by any suitable process known in the art such as, but not limited to, ink printing, laser assisted deposition, and paste deposition. For an embodiment, a laser assisted deposition process is used to form a second conductive material 505 in trace pattern 515. A laser assisted deposition process may include a series of two primary operations. The first operation includes improving the adhesion of trace pattern 515 by applying a laser source to the surface in the area where the conductive material is to be deposited such that the morphology of surface is abraded. The second operation may include applying a laser to a conductive source to fill the trace pattern 515 with the conductive material. Second conductive material 505 may include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. In one embodiment, second conductive material 505 includes a metal alloy or a compound that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. In other embodiments, second conductive material 505 may comprise another material or materials.

Second conductive material 505 may have a considerable level of porosity due to the laser assisted deposition method of fabrication. Likewise, according to an embodiment, the substrate 500 is subjected to a sintering process to densify second conductive material 505 for higher conductivity. The sintering process may include heating up the substrate 500 to increase the conductivity by reducing the porosity of second conductive material 505.

According to the second process taught above, a planarization process is not required due to the preciseness of the deposition process. Therefore, neither chemical deposition process (CMP) nor any other planarization process is required because the paste deposition process effectively forms the conductive materials within the trenches and patterns without excess deposition.

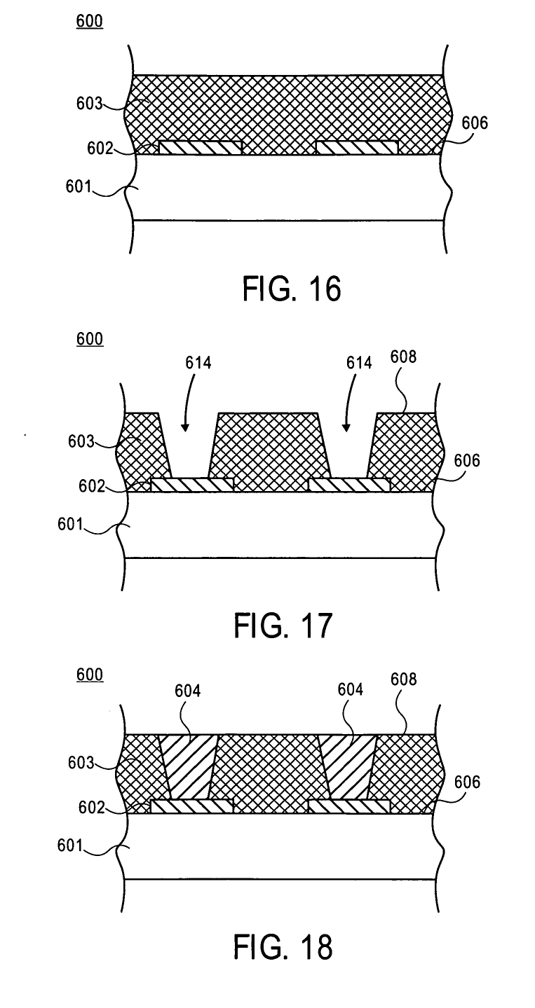

FIG. 16 is a cross-section of a substrate, illustrating the start of a process to fabricate a substrate according to a process embodiment defined by operations 301-302 and 309-314. As shown, a first dielectric layer 603 and conductive layers 602 are fabricated on a top surface 606 of core 601.

FIG. 17 shows the stage of the process after via openings 614 is formed in first dielectric layer 603 (309). For an embodiment, via openings 614 are formed by an ablation process. Via openings 614 extend from the top surface 608 of first dielectric layer 603 to conductive layers 602. For various embodiments, the depth of via openings 614 ranges from 20-60 microns and the diameter of via openings 614 ranges from 30-70 microns.

For an embodiment, a surface roughening process is applied to a substrate 600 to enhance the adhesion (operation 310). Although a surface roughening process is applied to a package substrate, FIG. 17 may not show a roughened surface as illustrated in FIG. 7.

FIG. 18 shows the stage of the process after a conductive material is formed in via openings 614 (operation 311). A conductive material may be formed by any suitable process such as, but not limited to, electroplating, ink printing, laser assisted deposition, and paste deposition. For an embodiment, an ink printing process is used to form a first conductive material 604 in via openings 614. For an embodiment, an ink printing process includes formulating a first conductive material 604 in a suspension or aeorosl and ejecting the first conductive material 604 through a nozzel into each via openings 614. For an embodiment, first conductive material 604 includes a nano particle ink material. For other embodiments, first conductive material 604 includes a micro particle ink or a combination of micro particle ink and nano particle ink materials.

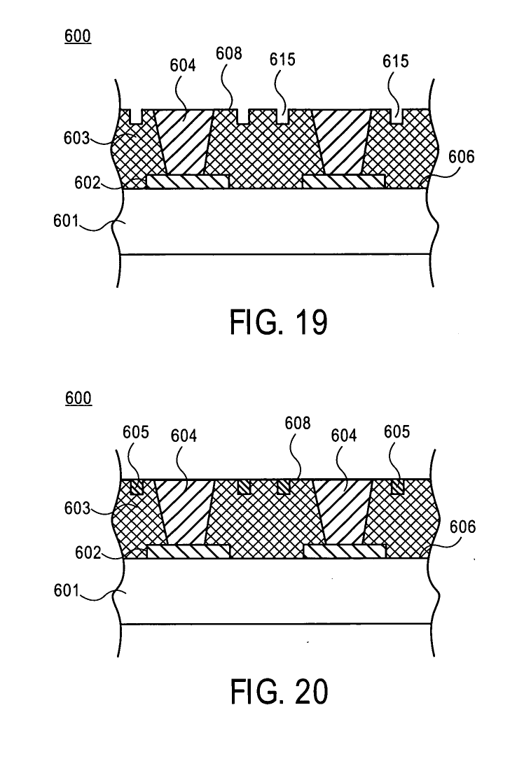

FIG. 19 shows the stage of the process after a trace pattern 615 is formed in first dielectric layer 603 (operation 312). For an embodiment, trace pattern 615 are formed by an ablation process. Trace pattern 615 may extend from the top surface of first dielectric layer 603 to conductive layers 602. For various embodiments, the depth of trace pattern 615 may range from 10-20 microns.

For an embodiment, a surface roughening process is applied to substrate 600 to enhance the adhesiveness of a conductive material subsequently formed thereon by abrading the exposed surface of trace pattern 615 (operation 313). Although a surface roughening process is applied to a package substrate, FIG. 19 may not show a roughened surface as illustrated in FIG. 7.

FIG. 20 shows the stage of the process after a conductive material is formed in trace pattern 615 (operation 314). A conductive material may be formed by any suitable process known in the art such as, but not limited to, ink printing, laser assisted deposition, and paste deposition. For an embodiment, an ink printing process is used to form a second conductive material 605 in trace pattern 615. For an embodiment, an ink printing process includes formulating a second conductive material 605 in a suspension or aerosol and ejecting the second conductive material 605 through a nozzel into each trace opening of trace pattern 615. For an embodiment, second conductive material 605 includes a nano particle ink material. For other embodiments, second conductive material 605 includes a micro-filler ink or a combination of micro particle ink and nano particle ink materials.

Second conductive material 605 may have a considerable amount of porosity due to the ink printing method of fabrication. Likewise, according to an embodiment, the substrate 600 is subjected to a sintering process to densify second conductive material 605 to increase conductivity. The sintering process may include heating up the substrate 600 to increase the conductivity by reducing the porosity of second conductive material 605.

In the foregoing specification, the invention has been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

1. An apparatus comprising:
a core;
a first dielectric layer disposed on a first side of said core;
a first via extending through said first dielectric layer; and
a first trace extending through a portion of said first dielectric layer, wherein said first trace is adjacent to said first via.

2. The apparatus of claim 1 further comprises a first conductive layer disposed flush with the first side of said core, wherein said via extends through said first dielectric layer to said first conductive layer.

3. The apparatus of claim 1 further comprises a plurality of traces fixed in said first dielectric layer.

4. The apparatus of claim 1, wherein the width of said first trace is less than 10 microns.

5. The apparatus of claim 1, wherein a second conductive layer, a second dielectric layer, a second via, and a second trace are disposed on a second side of said core such that said second conductive layer is flush with said second side of said core and said second via extends through said second dielectric layer to said second conductive layer and wherein said second trace is fixed in said second dielectric layer and adjacent to said second via.

6. A package substrate, comprising:
a core;
a conductive layer disposed flush to a top side of said core;
a dielectric layer disposed on said top side of said conductive layer, wherein a portion of said dielectric layer is adjacent to said conductive layer;
a via extending through said dielectric layer to said conductive layer;
a trace extending through a portion of said dielectric layer.

7. The package substrate of claim 6, wherein said dielectric layer is a build up dielectric layer.

8. The package substrate of claim 6, wherein the thickness of said dielectric layer ranges from 20 to 60 microns.

9. The method of claim 6 further comprising forming a build up dielectric layer on a second side of said core, wherein said core comprises a second conductive layer disposed flush to said second side; forming a via pattern to a first depth and a trace pattern to a second depth simultaneously in said build up dielectric layer; forming a third dielectric material in said via pattern and forming a fourth dielectric material in said trace pattern.

10. A method of forming a package substrate, comprising:
laminating a build up dielectric layer on a first side of a core, wherein said core comprises a conductive region disposed flush to said first side of said core;
ablating a via pattern in said build up dielectric layer to a first depth ablating a trace pattern in said build up dielectric layer to a second depth;
forming a first conductive material in said via pattern;
forming a second conductive material in said trace pattern.

11. The method of claim 10 further comprising applying a first sintering process after said first conductive material is formed and applying a second sintering process after said second conductive material is formed.

12. The method of claim 10, wherein said first depth is greater than said second depth.

13. The method of claim 10, wherein ablating said via pattern and said trace pattern comprises a laser ablation process.

14. The method of claim 10, wherein the composition of said first conductive material differs from the composition of said second conductive material.

15. The method of claim 10, wherein forming said first conductive material and said second conductive material comprises a method selected from the group consisting of a ink printing process, a paste deposition process, and a laser assisted deposition process.

16. A method of forming a package substrate, comprising:
laminating a first build up layer on a first side of a core, wherein said core comprises a conductive region disposed flush to a first side of said core;
ablating a via opening and a trace pattern concurrently in said first build up dielectric layer;
forming a first conductive material in said via pattern and a second conductive material in said trace pattern.

17. The method of claim 16 further comprising laminating a second build up layer on a second side of said core; ablating a via pattern and a trace opening concurrently in a second build up dielectric layer; forming a first conductive material in said via pattern and a second conductive material in said trace pattern.

18. The method of claim 16 further comprising applying a surface roughening process to said via opening and said trace pattern prior to said first and second conductive material formation.

19. The method of claim 16, wherein said first conductive material and said second conductive material comprises a nano-paste material.

20. The method of claim 16, wherein said first conductive material and said second conductive material comprises a nano-paste and a micro-paste material.
